(19) United States
(12) Patent Application Publication
(10) Pub. No.: US 2004/0030970 A1
(43) Pub. Date: Feb. 12, 2004

(54) Test platform device and method for testing embedded memory of system on chip

(76) Inventors: Murphy Chen, Taipei (TW); Timothy Tseng, Taipei (TW); Chao-Cheng Cheng, Taipei (TW); Ruth Lin, Taipei (TW); Mike Duh, Taipei (TW)

Correspondence Address: MADSON & METCALF, GATEWAY TOWER WEST, SUITE 900, 15 WEST SOUTH TEMPLE, SALT LAKE CITY, UT, 84101

(21) Appl. No.: 10/430,884

(22) Filed: May 7, 2003

(30) Foreign Application Priority Data
May 8, 2002 (TW) 091109541
Aug. 23, 2002 (TW) 091119181

(51) Int. Cl. G11C 29/00

(52) U.S. Cl. 714/718

(57) ABSTRACT

A test platform device for testing an embedded memory of a system on chip includes a first socket, a second socket and a test control circuit. The first socket is used for plugging therein the system on chip to be tested. The second socket is used for plugging therein an independent memory chip. The test control circuit is electrically connected to the first socket and the second socket, performs a comparable writing-reading operation of each of the embedded memory of the system on chip and the independent memory chip and outputting an error data when incomparable results are obtained in response to the comparable writing-reading operation of each of the embedded memory of the system on chip and the independent memory chip.

### FIELD OF THE INVENTION

The present invention relates to a test platform device and a method for testing a memory, and more particularly a test platform device and a method for testing an embedded memory of a system on chip (SOC).

### BACKGROUND OF THE INVENTION

Nowadays, a semiconductor integrated circuit principally includes two portions, i.e. a logic control circuit portion and a memory portion. Since these two portions have distinct functions and manufactured by different processes, they are generally made on different chips and then properly assembled. However, on account of many factors such as cost, reliability, operation speed, etc., an embedded chip, also called system on chip (SOC), is developed. Please refer to FIG. 1. A typical system on chip 1 principally comprises a logic control circuit 11 and an embedded memory 12, which are electrically connected with each other by means of an internal bus 13. With specialization of the production of each portion of a semiconductor integrated circuit, different companies are responsible for respective portions they are good at. Therefore, for example, the company specialized in designing logic control circuits may purchase embedded memories from another company, and then incorporate them into embedded chips. Taking a network switch control chip as an example, the designer of the control chip needs to obtain intellectual property (IP) of dynamic random access memory (DRAM) from another company in order to complete a single chip comprising the produced logic control circuit portion and the purchased memory portion.

In order to assure of normal operation of the control chip in connection with a new component, i.e. the embedded memory, a test procedure is done to verify the embedded chip. Unfortunately, since the embedded memory is buried inside the chip, it is difficult to be tested directly. Therefore, the test procedure is performed by means of an IC tester. By the IC tester, respective programs are provided for separately testing the logic control circuit portion and the embedded memory portion. The IC tester is capable of verifying a great amount of chips efficiently.

During typical operations, a logic control circuit is switched frequently, and used to working at a high temperature. Whereas, a memory is operated in a good environment, for example at a relatively low temperature. Since theses two components of the system on chip have different working conditions, they inevitably interfere with each other when they are combined in a system on chip. Therefore, the result of testing an embedded memory portion at the absence of the logic control circuit portion could not be applied to an actual system on chip in which the embedded memory portion operates at the presence of the logic circuit portion. Therefore, even if the memory test result is acceptable, the designer of embedded memories may still need to modify the embedded memory circuitry according to the factors influenced by the co-existing logic control circuit portion such as frequent switching actions and high heat radiation rate. On the other hand, logic control circuits with various functions and operation manners have different impacts on the same embedded memory in connection therewith. As a result, a system on chip with an embedded memory portion is required to perform a series of testing and modifying procedures in order to obtain an optimal embedded memory circuitry.

When the testing and modifying procedures are performed by an IC tester, various test patterns may need to be compiled for different procedures and thus it is time-consuming. In addition, the test algorithm suitable for testing a dynamic random access memory cannot be perfectly applied to all embedded memories. Therefore, many possible failure patterns might be neglected, and thus could not be recorded. Such long period spent for testing and modifying procedures is disadvantageous for increasing throughputs. These drawbacks described above attribute to a fact that the IC tester is not focused on debugging functions.

### SUMMARY OF THE INVENTION

It is an object of the present invention to provide a test platform device and a method for testing an embedded chip by performing an effective and efficient debugging procedure so as to avoid the above-mentioned drawbacks.

In accordance with a first aspect of the present invention, there is provided a test platform device for testing an embedded memory of a system on chip. The test platform device comprises a first socket, a second socket and a test control circuit. The first socket is used for plugging therein the system on chip to be tested. The second socket is used for plugging therein an independent memory chip. The test control circuit is electrically connected to the first socket and the second socket, performs a comparable writing-reading operation of each of the embedded memory of the system on chip and the independent memory chip and outputting an error data when incomparable results are obtained in response to the comparable writing-reading operation of each of the embedded memory of the system on chip and the independent memory chip.

Preferably, the test control circuit suspends the writing-reading operation of each of the embedded memory of the system on chip and the independent memory chip when the incomparable results are obtained.

In an embodiment, the first socket, the second socket and the test control circuit are mounted on a circuit board.

In an embodiment, the test platform device further comprises a computer electrically connected to the test control circuit and recording the error data. Preferably, the computer is electrically connected to the test control circuit via an intelligent device electronics (IDE) interface.

The test control circuit, for example, can be implemented by a field programmable gate array (FPGA).

In an embodiment, the first socket has a first specification compatible to a network switch control chip operated in a static random access memory (SRAM) direct access mode. On the other hand, the second socket has a second specification compatible to an independent memory compatible to a static random access memory (SRAM) direct access mode. Specifically, the independent memory has a memory capacity substantially equal to that of the network switch control chip.

In an embodiment, the test control circuit comprises a plurality of registers, a first random number generator, a second random number generator and a random command generator. The plurality of registers store therein a first threshold value and a second threshold value less than the first threshold value. The first random number generator is used for generating a random value as an input data. The second random number generator is used for generating a random address data. The random command generator is coupled to the plurality of registers and the first random number generator, performs the writing operation in accordance with the random address data when the random value is greater than or equal to the first threshold value, performs the reading operation when the random value is less than the first threshold value but greater than the second threshold value, and no operation is done when the random value is less than or equal to the second threshold value.

In accordance with a second aspect of the present invention, there is provided a test platform device for testing an embedded memory of a chip. The test platform device comprises a reference circuit, a socket and a test control circuit. The reference circuit comprises an independent memory compatible to a first memory specification. The socket is used for plugging therein the chip to be tested. The embedded memory of the chip has a second memory specification, the operations of which are able to be accomplished by the independent memory of the first memory specification. The test control circuit is electrically connected to the socket and the reference circuit, and performs a test operation by writing test data into both of the embedded memory and independent memory and then reading the test data from both of the embedded memory and the independent memory, wherein an error data is outputted by the test control circuit when the test data read from the embedded memory and the independent memory are inconsistent with each other.

In an embodiment, the independent memory is operated in a static random access memory (SRAM) direct access mode.

In an embodiment, the chip is a network switch control chip operated in a static random access memory (SRAM) direct access mode, and the independent memory has a memory capacity greater than or equal to that of an embedded memory of the network switch control chip.

In an embodiment, the test data written into both of the embedded memory and independent memory in the test operation are identical.

In accordance with a third aspect of the present invention, there is provided a method for testing an embedded memory of a system on chip. Firstly, an independent memory capable of performing operating behaviors of the embedded memory is provided. Test data are written into and then read from both of the embedded memory and the independent memory. Then, an error data of the embedded memory is outputted when the test data read from the embedded memory and the independent memory are inconsistent with each other.

In an embodiment, the method further comprises steps of: suspending writing further test data into the embedded memory and the independent memory; and recording and analyzing the error data.

In an embodiment, the independent memory has a memory capacity greater than or equal to that of the embedded memory.

In an embodiment, the chip is a network switch control chip in a static random access memory (SRAM) direct access mode, and the independent memory is operated in a static random access memory (SRAM) direct access mode.

In an embodiment, identical data are written as the test data.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic circuit block diagram illustrating a typical system on chip; and

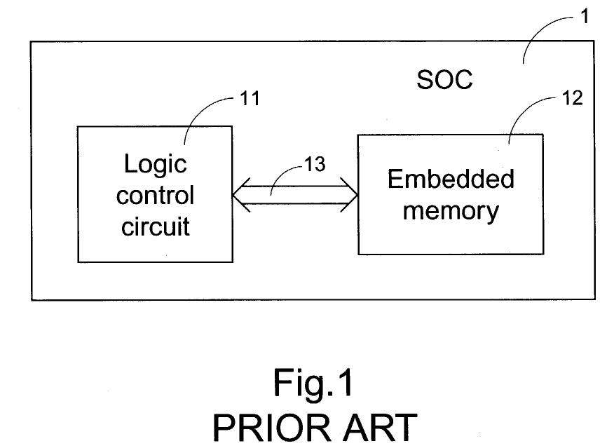

FIG. 2 is a schematic circuit block diagram illustrating a test platform device for testing an embedded chip according to a preferred embodiment of the present invention.

### DETAILED DESCRIPTION OF THE PREFERRED EMBODIMENT

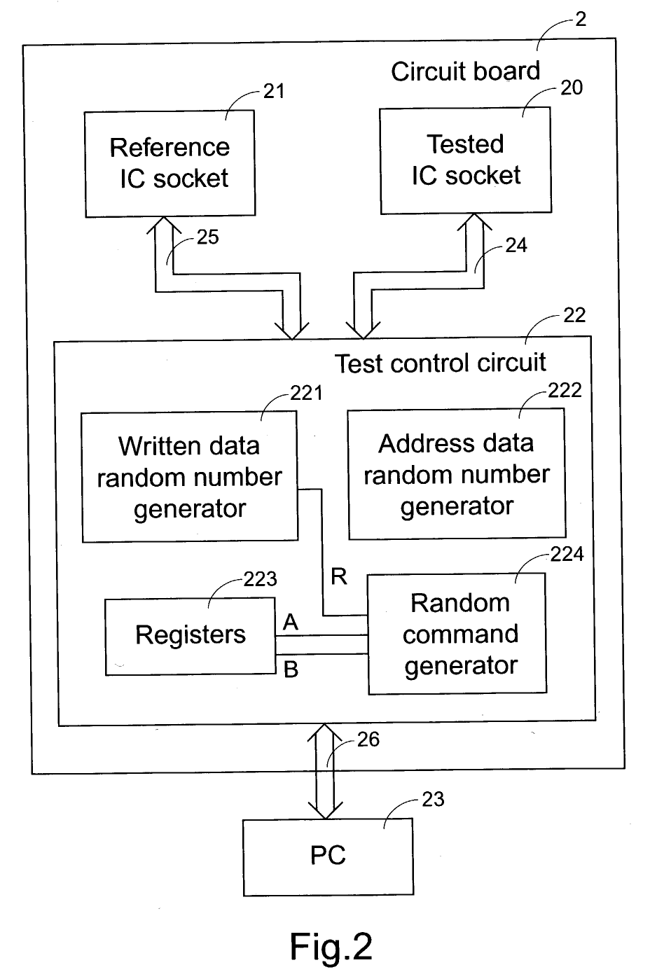

An embodiment of the test platform device shown in FIG. 2 comprises a tested IC socket 20, a reference IC socket 21 and a test control circuit 22, all of which are mounted on a circuit board 2. A system on chip (SOC) with an embedded memory to be tested is plugged into the tested IC socket 20. For testing the SOC embedded memory, another chip having an independent memory is plugged into the reference IC socket 21 for reference of the test control circuit 22. An independent memory having a memory capacity greater than or equal to that of the embedded memory of the system on chip and operating behaviors identical to or better than those of the SOC embedded memory is selected as the reference circuit. The independent memory chip has been verified for obtaining a reliable test result.

Firstly, identical test data are written into both the embedded memory of the system on chip and the independent memory via the IC socket 20 and the memory socket 21, respectively. Then, data stored at the same addresses in the embedded memory and the independent memory as the written test data are read out and compared. When the data read from the embedded memory and the independent memory are inconsistent with each other, it is determined that error occurs, and the test control circuit 22 suspends the subsequent writing and reading operation. Meanwhile, the test control circuit 22 asserts an interrupt signal and outputs an error data to a personal computer 23, which is provided for monitoring and recording the testing results. For example, in response to the interrupt signal, a program executed on the computer 23 performs retrieving and storing operations to store the error data including the error spot, several previous commands, and several addresses relating to the address of the erroneous test data, e.g. several preceding or following addresses of the address of the erroneous test data. Then, the writing and reading operations continues to be performed to finding next error data, if existent. The above testing procedures could be repeated to obtain sufficient information about the incomparable results so as to provide an appropriate countermeasure.

The test control circuit 22 is electrically connected to the tested IC socket 20 and the reference IC socket 21 via transmitting channels 24 and 25, respectively. In order to increase designing flexibility, the test control circuit 22 is implemented by a field programmable gate array (FPGA)/complex programmable logic device (CPLD). The operating strategy according to the test control circuit 22 will be illustrated as follows. The present invention will be described in more details by taking a network switch control chip as an example of the tested IC. The network switch control chip comprises a logic control circuit and an embedded memory, both produced by different suppliers. The embedded memory applied to a network switch control chip of high processing speed is preferably a zero bus turnaround static random access memory (ZBT-SRAM). Accordingly, a memory having been verified and having a memory capacity greater than or equal to that of the ZBT-SRAM is selected as the independent memory. As for the test control circuit 22, a field programmable gate array (FPGA) commercially available from Xilinx, USA is used in this example.

The transmitting channel 24 connecting the IC socket 20 and the test control circuit 22 comprises a data signal transmitting line of 32-bits, an address signal transmitting line of 14-bits, a signal-reading line, a signal-writing line, a signal reset signal line and a clock signal line. Likewise, the transmitting channel 25 connecting the memory socket 21 and the test control circuit 22 comprises a data signal transmitting line of 32 bits, an address signal transmitting line of 14 bits, a signal-reading line, a signal-writing line, a signal reset signal line and a clock signal line. The transmission channel 26 connecting the test control circuit 22 and the computer 23 is an intelligent device electronics (IDE) interface of 8 bits.

In order to generate the 32-bit written data for memory test and the 14-bit address data for locating the written data at random, the test control circuit 22 shown in FIG. 2 comprises a written data random number generator 221 and an address data random number generator 222. In addition, the test control circuit 22 comprises a plurality of internal registers 223 and a random command generator 224. The random command generator 224 is coupled to the plurality of internal registers 223 and the written data random number generator 221.

The plurality of internal registers 223 comprises many kinds of registers for storing various functional parameters. They, for example, include the register for asserting/de-asserting reset signal to the network switch control chip, the register for asserting/de-asserting reset signal to the ZBT-SRAM, the register for outputting SRAM clock frequency select signal, the register for indirect access to the SRAM, the random number generator seed register, the register for triggering kicking off grinder, the register for triggering to clear the SRAM of the network switch control chip, the register for triggering to clear the ZBT-SRAM, two threshold registers for selecting the possibility of read/write/idle commands, the register for triggering to reset software, and the 5 sets of registers for recording the operations in four previous cycles and the command/address/failed data, etc, of the current cycle.

For example, for the two threshold registers, a high threshold value A and a low threshold value B are stored in the registers for selecting the possibility of read/write/idle commands. When the random value R generated from the written data random number generator 221 is greater than or equal to the high threshold value A, the random command generator 224 performs a writing operation. When the random value R is less than the high threshold value A but greater than the low threshold value B, the random command generator 224 performs a reading operation. Whereas, no operation is done when the random value R is less than or equal to the low threshold value B.

The software program executed in the computer 23 comprises the following steps:

(a) performing a software resetting procedure so as to allow the software to be compatible to a test control circuit 22 implemented by a field programmable gate array (FPGA);

(b) loading random seeds into the random number generators 221 and 222;

(c) setting the threshold values A and B in the registers 223 for the possibility of read/write/idle commands;

(d) selecting SRAM clock outputs to be operated in a SRAM direct access mode;

(e) resetting the switch control chip;

(f) resetting the ZBT-SRAM;

(g) selecting 32 bits of data from the network switch control chip to be tested;

(h) clearing both the SRAM of the network switch control chip and ZBT-SRAM;

(i) kicking off grinder;

(j) waiting an interrupt signal from FPGA; and

(k) when the interrupt signal is received, reading history 5 cycles log, reading the other 3 words in 512-bit column containing the failed 32-bit data, reading neighboring words in neighboring columns, clearing the inconsistent word in the SRAM of the network switch control chip and ZBT-SRAM, and then kicking off the grinder to continue.

Since a ZBT-SRAM is used as the independent memory required to be verified and have a memory capacity greater than or equal to that of the embedded SRAM, the inconsistent test data read from the embedded memory and the independent memory represent some errors occur in the embedded memory of the network switch control chip. In addition, the software program executed in the computer 23 triggers the test control circuit 22 to output a test report associated with the inconsistent test data to the computer 23 via the IDE. By means of the test platform device and the method of the present invention, the possible errors of the embedded memory of the system on chip could be effectively and efficiently detected and provided for the reference of the memory manufacturer to modify his design. Furthermore, the present invention can also be applied to cycle based read/write tests to find specified failure patterns, so that the field programmable gate array (FPGA) can be rewritten to have a modified test algorithm suitable for serving another test control circuit for the test of various SOCs.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A test platform device for testing an embedded memory of a system on chip, said test platform device comprises:
a first socket for plugging therein said system on chip to be tested;
a second socket for plugging therein an independent memory chip; and
a test control circuit electrically connected to said first socket and said second socket, performing a comparable writing-reading operation of each of said embedded memory of said system on chip and said independent memory chip and outputting an error data when incomparable results are obtained in response to said comparable writing-reading operation of each of said embedded memory of said system on chip and said independent memory chip.

2. The test platform device according to claim 1 wherein said test control circuit suspends said writing-reading operation of each of said embedded memory of said system on chip and said independent memory chip when said incomparable results are obtained.

3. The test platform device according to claim 1 wherein said first socket, said second socket and said test control circuit are mounted on a circuit board.

4. The test platform device according to claim 1 further comprising a computer electrically connected to said test control circuit and recording said error data.

5. The test platform device according to claim 4 wherein said computer is electrically connected to said test control circuit via an intelligent device electronics (IDE) interface.

6. The test platform device according to claim 1 wherein said test control circuit is implemented by a field programmable gate array (FPGA).

7. The test platform device according to claim 1 wherein said first socket has a first specification compatible to a network switch control chip of a static random access memory (SRAM) direct access mode.

8. The test platform device according to claim 7 wherein said second socket has a second specification compatible to an independent memory of a static random access memory (SRAM) direct access mode.

9. The test platform device according to claim 8 wherein said independent memory has a memory capacity substantially equal to that of said network switch control chip.

10. The test platform device according to claim 1 wherein said test control circuit comprises:
a plurality of registers storing therein a first threshold value and a second threshold value less than said first threshold value;
a first random number generator for generating a random value as an input data;
a second random number generator for generating a random address data; and
a random command generator coupled to said plurality of registers and said first random number generator, performing said writing operation in accordance with said random address data when said random value is greater than or equal to said first threshold value, performing said reading operation when said random value is less than said first threshold value but greater than said second threshold value, and performing nothing when said random value is less than or equal to said second threshold value.

11. A test platform device for testing an embedded memory of a chip, said test platform device comprises:
a reference circuit comprising an independent memory compatible to a first memory specification;
a socket for plugging therein said chip to be tested, said embedded memory of said chip having a second memory specification, the operations of which are able to be accomplished by said independent memory of said first memory specification; and
a test control circuit electrically connected to said socket and said reference circuit, and performing a test operation by writing test data into both of said embedded memory and independent memory and then reading said test data from both of said embedded memory and said independent memory, wherein an error data is outputted by said test control circuit when said test data read from said embedded memory and said independent memory are inconsistent with each other.

12. The test platform device according to claim 11 wherein said independent memory is operated in a static random access memory (SRAM) direct access mode.

13. The test platform device according to claim 11 wherein said chip is a network switch control chip operated in a static random access memory (SRAM) direct access mode, and said independent memory has a memory capacity greater than or equal to that of an embedded memory of said network switch control chip.

14. The test platform device according to claim 11 wherein said test data written into both of said embedded memory and independent memory in said test operation are identical.

15. A method for testing an embedded memory of a system on chip, said method comprising steps of:
providing an independent memory capable of performing operating behaviors of said embedded memory;
writing test data into and then reading said test data from both of said embedded memory and said independent memory; and
outputting an error data of said embedded memory when said test data read from said embedded memory and said independent memory are inconsistent with each other.

16. The method according to claim 15 further comprising steps of:
suspending writing further test data into said embedded memory and said independent memory; and
recording and analyzing said error data.

17. The method according to claim 15 wherein said independent memory has a memory capacity greater than or equal to that of said embedded memory.

18. The method according to claim 15 wherein said chip is a network switch control chip in a static random access memory (SRAM) direct access mode, and said independent memory is operated in a static random access memory (SRAM) direct access mode.

19. The method according to claim 15 wherein identical data are written as said test data.
